(19) United States
(12) Patent Application Publication
(10) Pub. No.: US 2025/0160087 A1
(43) Pub. Date: May 15, 2025

(54) DEVICE FOR MANUFACTURING DISPLAY DEVICE

(71) Applicant: LG ELECTRONICS INC., Seoul (KR)

(72) Inventors: Gunho KIM, Seoul (KR); Bongchu SHIM, Seoul (KR); Yongil SHIN, Seoul (KR); Jungsub KIM, Seoul (KR)

(73) Assignee: LG ELECTRONICS INC., Seoul (KR)

(21) Appl. No.: 18/839,220

(22) PCT Filed: Feb. 17, 2022
(86) PCT No.: PCT/KR2022/002322

§ 371 Date: Aug. 16, 2024

(51) Int. Cl. H10H 29/03; C25D 13/12; C25D 13/18; H01L 21/67

(52) U.S. Cl. CPC H10H 29/03; C25D 13/12; C25D 13/18; H01L 21/67144

(57) ABSTRACT

A manufacturing device for a display device comprises: a chamber in which a display substrate is installed and comprises a fluid; a magnetic member on one side of the display substrate; And a signal supply device is included, wherein the signal supply device modulates a first alternating current signal into a second alternating current signal and supplies the modulated second alternating current signal to electrode wiring of the display substrate, and the second alternating current signal periodically changes a dielectrophoretic force to attach and detach a plurality of semiconductor light-emitting elements contained in the fluid to a plurality of assembly holes of the display substrate, respectively.

### TECHNICAL FIELD

The embodiment relates to a display device, and more specifically, to a device for manufacturing a display device.

### BACKGROUND ART

Large-area displays comprise liquid crystal displays (LCDs), OLED displays, and micro-LED displays.

A micro-LED display is a display that uses micro-LEDs, which are semiconductor light-emitting elements with a diameter or cross-sectional area of 100 μm or less, as display elements.

Since a micro-LED display uses micro-LEDs, which are semiconductor light-emitting elements, as display elements, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution by separating and combining the screen in a modular manner, and the advantage of being able to implement a flexible display.

However, since large micro-LED displays require millions or more micro-LEDs, there is a technical problem in quickly and accurately transferring micro-LEDs to the display panel.

Transfer technologies that are being developed recently comprise the pick and place process, the laser lift-off method, or the self-assembly method.

Among these, the self-assembly method is a method in which semiconductor light-emitting elements find their own assembly positions within a fluid, which is advantageous for implementing large-screen display devices.

According to a non-public internal technology, a plurality of semiconductor light-emitting elements that emit different color light are individually assembled. For example, a first semiconductor light-emitting element is put into a fluid and assembled onto a display substrate, a second semiconductor light-emitting element is put into a fluid and assembled onto a display substrate, and a third semiconductor light-emitting element is put into a fluid and assembled onto a display substrate.

However, according to this individual assembly method, since the first semiconductor light-emitting element, the second semiconductor light-emitting element, and the third semiconductor light-emitting element are individually assembled on the display substrate, there is a problem that the process time takes too long.

To solve this problem, according to the non-public internal technology, a technology has been developed in which the first semiconductor light-emitting element, the second semiconductor light-emitting element, and the third semiconductor light-emitting element are simultaneously assembled on the display substrate, thereby dramatically reducing the process time. That is, the first semiconductor light-emitting element, the second semiconductor light-emitting element, and the third semiconductor light-emitting element are simultaneously injected into the fluid, and the first semiconductor light-emitting element, the second semiconductor light-emitting element, and the third semiconductor light-emitting element are each assembled on the corresponding sub-pixel of the display substrate.

However, according to this simultaneous assembly method, there is a problem that the semiconductor light-emitting element causes a color mixing defect in which it is assembled on a sub-pixel other than the sub-pixel to which it is to be assembled. For example, the first semiconductor light-emitting element should be assembled on the first sub-pixel of the display substrate, but it may be assembled on the second sub-pixel or the third sub-pixel. Originally, a second semiconductor light-emitting element should be assembled into the second sub-pixel, and a third semiconductor light-emitting element should be assembled into the third sub-pixel.

In the following description of the invention, assembling a semiconductor light-emitting element into a corresponding sub-pixel of a display substrate is called correct assembly, and assembling a semiconductor light-emitting element into a sub-pixel other than a corresponding sub-pixel of a display substrate is called incorrect assembly.

When implementing a display of a display device equipped with a plurality of semiconductor light-emitting elements that cause color mixing defects in this way, the first color light should be emitted by the correct assembly of the semiconductor light-emitting elements in the first sub-pixel, but the second color light or the third color light is emitted by the incorrect assembly of the semiconductor light-emitting elements. Therefore, white light should be formed by the first sub-pixel, the second sub-pixel, and the third sub-pixel for display implementation, but there is a problem in which a desired color image may not be realized because a specific color light is not emitted due to incorrect assembly of a semiconductor light-emitting element, so that white light is not formed.

### DISCLOSURE

### Technical Problem

An object of the embodiment is to solve the foregoing and other problems.

Another object of the embodiment is to provide a device for manufacturing a display device implemented using a process method capable of drastically shortening the process time.

In addition, another object of the embodiment is to provide a device for manufacturing a display device capable of improving the correct assembly rate.

In addition, another object of the embodiment is to provide a device for manufacturing a display device capable of preventing color mixing defects.

The technical problems of the embodiments are not limited to those described in this item and comprise those that can be understood through the description of the invention.

### Technical Solution

In order to achieve the above or other objects, according to one aspect of the embodiment, a device for manufacturing a display device, comprises: a chamber in which a display substrate is installed and comprising a fluid; a magnetic member on one side of the display substrate; and a signal supply device, wherein the signal supply device is configured: to modulate a first alternating current signal into a second alternating current signal and to supply the modulated second alternating current signal to electrode wiring of the display substrate, and wherein the second alternating current signal is configured to periodically change a dielectrophoretic force to attach and detach a plurality of semiconductor light-emitting elements contained in the fluid to a plurality of assembly holes of the display substrate, respectively.

The signal supply device may comprise an alternating current signal generation unit that generates the first alternating current signal; a control signal generation unit that generates a control signal; and a modulation unit that modulates the first alternating current signal into the second alternating current signal according to the control signal.

The modulation unit may modulate the control signal into a symmetrical waveform symmetrical to a time axis, and generate a waveform corresponding to the modulated symmetrical waveform among the waveforms of the first alternating current signal as the waveform of the second alternating current signal.

The control signal may be configured as a waveform having an ON section and an OFF section as one period. The second alternating current signal may have a second-first alternating current signal corresponding to the ON section and a second-second alternating current signal corresponding to the OFF section, and the second-first alternating current signal may have a square waveform. The dielectrophoretic force may be formed by the second-first alternating current signal, and the dielectrophoretic force may not be formed by the second-second alternating current signal.

A duty ratio is a ratio of the ON section to a sum of the ON section and the OFF section, and the duty ratio may be 30% to 70%.

The control signal may be configured as a waveform having a first OFF section, an ON section, and a second OFF section as one period. The waveform may comprise one of a triangular waveform or a sine waveform. The second alternating current signal may have a second-first alternating current signal corresponding to the first OFF section, a second-second alternating current signal corresponding to the ON section, and a second-third alternating current signal corresponding to the second OFF section. The above second-first alternating current signal may have an amplitude that increases from 0 to a first value, the second-second alternating current signal may have an amplitude that increases from the first value to a peak value and then decreases from the peak value to a second value, and the second-third alternating current signal may have an amplitude that decreases from the second value to 0. The dielectrophoretic force may be formed during a specific section between a first point corresponding to the first value and a second point corresponding to the second value, and the dielectrophoretic force may not be formed before the first point or after the second point.

The plurality of semiconductor light-emitting elements may comprise a plurality of first semiconductor light-emitting elements, a plurality of second semiconductor light-emitting elements, and a plurality of third semiconductor light-emitting elements. The shape of each of the first semiconductor light-emitting element, the second semiconductor light-emitting element, and the third semiconductor light-emitting element is different, and the plurality of assembly holes comprise a plurality of first assembly holes, a plurality of second assembly holes, and a plurality of third assembly holes, and the shapes of the first assembly hole, the second assembly hole, and the third assembly hole may correspond to the shapes of the first semiconductor light-emitting element, the second semiconductor light-emitting element, and the third semiconductor light-emitting element, respectively.

By changing the dielectrophoretic force, the first semiconductor light-emitting element assembled into the first assembly hole may be maintained in the assembly, and the second semiconductor light-emitting element or the third semiconductor light-emitting element assembled into the first assembly hole can be detached.

### Advantageous Effects

The embodiment dramatically shortens the process time by simultaneously assembling a plurality of first semiconductor light-emitting elements, a plurality of second light-emitting elements, and a plurality of third semiconductor light-emitting elements on the entire surface of a display substrate, and when a semiconductor light-emitting element that does not fit the corresponding assembly hole is incorrectly-assembled, the incorrectly-assembled semiconductor light-emitting element may be detached to improve the correct assembly rate and prevent color mixing, thereby enhancing the reliability of the product.

To this end, as shown in FIG. 7, FIG. 9, and FIG. 14, the signal supply device 440 can modulate the first alternating current signal AC1 using the control signal COT to generate the second alternating current signal AC2. The waveform of the second alternating current signal AC2 can be generated using the waveform of the control signal COT. For example, when the control signal COT has a rectangular waveform, the second alternating current signal AC2 can also have a rectangular waveform.

For example, the second alternating current signal AC2 may have an ON section Ton having a second-first alternating current signal 411 having a high level and an OFF section Toff baving a second-second alternating current signal 412 having a low level, for example, a 0 level, with one period F2. Accordingly, a dielectrophoretic force may be formed between the first assembling wiring 321 and the second assembling wiring 322 of each of the first sub-pixel PX1, the second sub-pixel PX2, and the third sub-pixel PX3 by the second-first alternating current signal 411 supplied to the ON section Ton of one period F2, so that the first semiconductor light-emitting element 150-1, the second semiconductor light-emitting element 150-2, and the third semiconductor light-emitting element 150-3 may be assembled into the assembly holes 330H of each of the first sub-pixel PX1, the second sub-pixel PX2, and the third sub-pixel PX3.

At this time, the first semiconductor light-emitting element 150-1, the second semiconductor light-emitting element 150-2, and/or the third semiconductor light-emitting element 150-3 can be incorrectly-assembled into the corresponding assembly holes. Here, incorrect assembly means that a semiconductor light-emitting element that does not fit into the corresponding assembly hole is assembled into the corresponding assembly hole. The incorrectly-assembled first semiconductor light-emitting element 150-1, the second semiconductor light-emitting element 150-2, and/or the third semiconductor light-emitting element 150-3 must be removed from the corresponding assembly holes in order to prevent color mixing and improve the correct assembly rate.

According to an embodiment, the first semiconductor light-emitting element 150-1, the second semiconductor light-emitting element 150-2 and/or the third semiconductor light-emitting element 150-3, which are incorrectly-assembled in the assembly hole 330H of the first sub-pixel PX1, the second sub-pixel PX2 and/or the third sub-pixel PX3, can be easily detached by the second-second alternating current signal 412 supplied in the OFF section Toff of one period F2.

Meanwhile, since the second-first alternating current signal 411 and the second-second alternating current signal 412 may be periodically supplied to the display substrate 300, even if the mis-assembled first semiconductor light-emitting device 150-1, the second semiconductor light-emitting device 150-2 and/or the third semiconductor light-emitting device 150-3 is not detached from the assembly hole due to the second-second alternating current signal 412 supplied during the OFF section Toff of the previous period, the mis-assembled first semiconductor light-emitting device 150-1, the second semiconductor light-emitting device 150-2 and/or the third semiconductor light-emitting device 150-3 can be detached from the assembly hole due to the second-second alternating current signal 412 supplied during the OFF section Toff of the next period.

According to an embodiment, as shown in FIGS. 7, 9, and 17, the signal supply device 440 can modulate the first alternating current signal AC1 using a control signal COT having a triangular waveform to generate the second alternating current signal AC2 having a triangular waveform.

According to an embodiment, as shown in FIGS. 7, 9, and 18, the signal supply device 440 can modulate the first alternating current signal AC1 using a control signal COT having a sine waveform to generate the second alternating current signal AC2 having a sine waveform.

According to an embodiment, as shown in FIGS. 7, 9, and 20, the duty ratio of the control signal COT can be adjusted to adjust the duty ratio of the second alternating current signal AC2. For example, when the duty ratio of the second alternating current signal AC2 is 30% to 70%, the detachment of the mis-assembled semiconductor light-emitting element is accelerated, so that the correct assembly rate can be improved and color mixing can be prevented.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a living room of a house in which a display device according to the embodiment is disposed.

FIG. 2 is a block diagram schematically showing a display device according to the embodiment.

FIG. 3 is a circuit diagram showing an example of a pixel of FIG. 2.

FIG. 4 is an enlarged view of the first panel area of the display device of FIG. 1.

FIG. 5 is an enlarged view of the A2 area of FIG. 4.

FIG. 6 is a drawing showing an example in which a light-emitting element according to the embodiment is assembled on a substrate by a self-assembly method.

FIG. 7 illustrates a device for manufacturing a display device according to the embodiment.

FIG. 8 is a plan view illustrating a plurality of semiconductor light-emitting elements having different shapes.

FIG. 9 is a block diagram illustrating a signal supply device of FIG. 7.

FIG. 10A illustrates a waveform of a first alternating current signal.

FIG. 10B is an enlarged view of area A of FIG. 10A.

FIG. 11 illustrates a waveform of a control signal having one period.

FIG. 12 illustrates a waveform of a second alternating current signal.

FIG. 13 illustrates a modulation pattern of a control signal.

FIG. 14 illustrates a pattern of modulating a first alternating current signal into a second. alternating current signal according to a first embodiment.

FIG. 15 illustrates an assembled pattern of a semiconductor light-emitting element when a dielectrophoretic force is formed.

FIG. 16 illustrates an assembled pattern of a semiconductor light-emitting element when a dielectrophoretic force is not formed.

FIG. 17 illustrates a modulation of a first alternating current signal into a second alternating current signal according to a second embodiment.

FIG. 18 illustrates a modulation of a first alternating current signal into a second alternating current signal according to a third embodiment.

FIG. 19 illustrates a comparative example and a correct assembly rate in the first to third embodiments.

FIG. 20 illustrates a second alternating current signal according to a duty ratio according to the fourth embodiment.

FIG. 21 illustrates a correct assembly rate according to a duty ratio.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display device described in this specification may comprise TV, signage, mobile phone, smart phone, head-up display (HUD) for automobile, backlight unit for laptop computers display for VR or AR, etc. However, the configuration according to the embodiment described in this specification can be applied to a new product type developed in the future, as well as a device capable of display.

Hereinafter, a light-emitting element according to an embodiment and a display device comprising the same will be described.

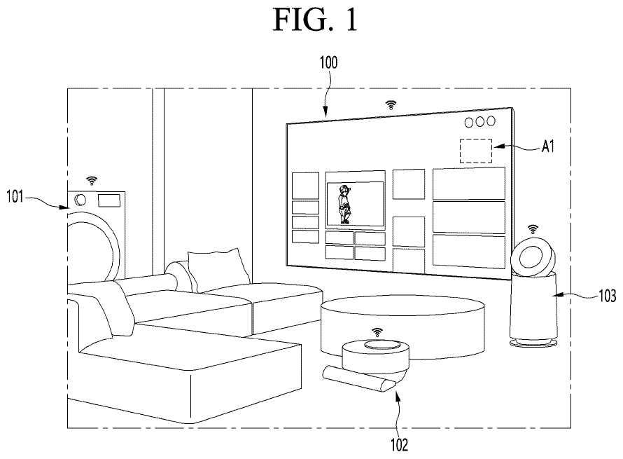

FIG. 1 illustrates a living room of a house in which a display device according to an embodiment is disposed.

Referring to FIG. 1, the display device 100 according to the embodiment can display the status of various electronic products such as a washing machine 101, a robot vacuum cleaner 102, and an air purifier 103, and can communicate with each electronic product based on IoT and control each electronic product based on user setting data.

The display device 100 according to the embodiment can comprise a flexible display manufactured on a thin and flexible substrate. The flexible display can be bent or rolled like paper while maintaining the characteristics of an existing flat display.

In the flexible display, visual information can be implemented by independently controlling the light emission of unit pixels disposed in a matrix form. A unit pixel means a minimum unit for implementing one color. A unit pixel of a flexible display can be implemented by a light-emitting element. In an embodiment, the light-emitting element may be a Micro-LED or a Nano-LED, but is not limited thereto.

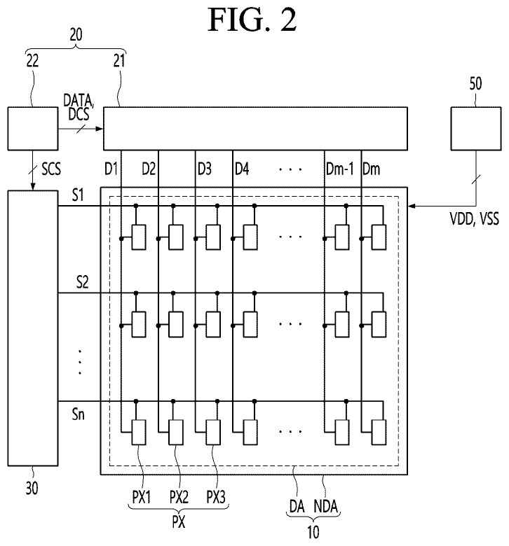

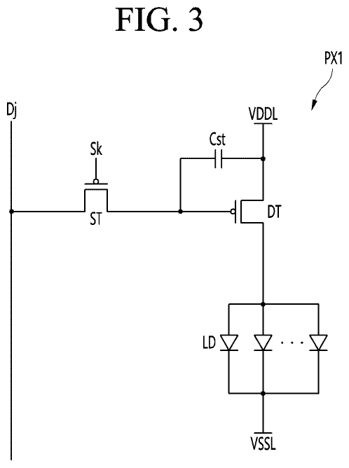

FIG. 2 is a block diagram schematically showing a display device according to an embodiment, and FIG. 3 is a circuit diagram showing an example of a pixel of FIG. 2.

Referring to FIGS. 2 and 3, the display device according to an embodiment may comprise a display panel 10, a driving circuit 20, a scan driving unit 30, and a power supply circuit 50.

The display device 100 of the embodiment may drive a light-emitting element in an active matrix (AM) method or a passive matrix (PM) method.

The driving circuit 20 may comprise a data driving unit 21 and a timing control unit 22,

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 may be divided into a display area DA and a non-display area NDA disposed around the display area DA. The display area DA is an area where pixels PX are formed and display an image. The display panel 10 may comprise data lines (D1 to Dm, m is an integer greater than or equal to 2), scan lines (S1 to Sn, n is an integer greater than or equal to 2) crossing the data lines D1 to Dm, a high-potential voltage line VDDL to which a high-potential voltage is supplied, a low-potential voltage line VSSL to which a low-potential voltage is supplied, and pixels PX connected to the data lines D1 to Dm and the scan lines S1 to Sn.

Each of the pixels PX may comprise a first sub-pixel PX1, a second sub-pixel PX2, and a third sub-pixel PX3. The first sub-pixel PX1 may emit a first color light of a first dominant wavelength, the second sub-pixel PX2 may emit a second color light of a second dominant wavelength, and the third sub-pixel PX3 may emit a third color light of a third dominant wavelength. The first color light may be red light, the second color light may be green light, and the third color light may be blue light, but is not limited thereto. In addition, although FIG. 2 illustrates that each of the pixels PX comprises three sub-pixels, the present invention is not limited thereto. That is, each of the pixels PX may comprise four or more sub-pixels.

Each of the first sub-pixel PX1, the second sub-pixel PX2, and the third sub-pixel PX3 may be connected to at least one of the data lines D1 to Dm, at least one of the scan lines S1 to Sn, and a high-potential voltage line VDDL. The first sub-pixel PX1 may comprise light-emitting elements LD, a plurality of transistors for supplying current to the light-emitting elements LD, and at least one capacitor Cst, as shown in FIG. 3.

Although not shown in the drawing, each of the first sub-pixel PX1, the second sub-pixel PX2, and the third sub-pixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as shown in FIG. 3. The driving transistor DT may comprise a gate electrode connected to the source electrode of the scan transistor ST, a source electrode connected to a high-potential voltage line VDDL to which a high-potential voltage is supplied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between the gate voltage and the source voltage of the driving transistor DT.

The driving transistor DT and the scan transistor ST may be formed of a thin film transistor. In addition, in FIG. 3, the driving transistor DT and the scan transistor ST are described mainly as being formed as P-type MOSFETs (Metal Oxide Semiconductor Field Effect Transistors), but the present invention is not limited thereto. The driving transistor DT and the scan transistor ST may also be formed as N-type MOSFETs. In this case, the positions of the source electrodes and the drain electrodes of each of the driving transistor DT and the scan transistor STs may be changed.

In addition, in FIG. 3, the first sub-pixel PX1, the second sub-pixel PX2, and the third sub-pixel PX3 are illustrated as comprising 2T1C (2 Transistor-1 capacitor) having one driving transistor DT, one scan transistor ST, and one capacitor Cst, but the present invention is not limited thereto. The first sub-pixel PX1, the second sub-pixel PX2, and the third sub-pixel PX3 may each comprise a plurality of scan transistors STs and a plurality of capacitors Csts.

The second sub-pixel PX2 and the third sub-pixel PX3 can be expressed by substantially the same circuit diagram as the first sub-pixel PX1, so that a detailed description thereof is omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts the digital video data DATA into analog data voltages according to the source control signal DCS and supplies the same to the data lines D1 to Dm of the display panel 10.

The timing control unit 22 receives digital video data DATA and timing signals from the host system. The timing signals may comprise a vertical synchronization signal, a horizontal synchronization signal, a data enable signal, and a dot clock. The host system may be an application processor of a smartphone or tablet PC, a monitor, a system on chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display area NDA provided on one side of the display panel 10. The driving circuit 20 may be formed as an integrated circuit (IC) and mounted on the display panel 10 in a chip on glass (COG) manner, a chip on plastic (COP) manner, or an ultrasonic bonding manner, but the present invention is not limited thereto. For example, the driving circuit 20 may be mounted on a circuit board (not shown) other than the display panel 10.

The data driving unit 21 may be mounted on the display panel 10 in a chip on glass (COG) manner, a chip on plastic (COP) manner, or an ultrasonic bonding manner, and the timing control unit 22 may be mounted on the circuit board.

The scan driving unit 30 receives a scan control signal SCS from the timing control unit 22. The scan driving unit 30 generates scan signals according to the scan control signal SCS and supplies the scan signals to the scan lines S1 to Sn of the display panel 10. The scan driving unit 30 may comprise a plurality of transistors and may be formed in a non-display area NDA of the display panel 10. Alternatively, the scan driving unit 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, lead lines of the circuit board may be electrically connected to the pads. The circuit board may be a flexible film, such as a flexible printed circuit board, a printed circuit board, or a chip on film. The circuit board may be bent to the bottom of the display panel 10. As a result, one side of the circuit board may be attached to one edge of the display panel 10, and the other side may be disposed on the bottom of the display panel 10 and connected to a system board on which a host system is mounted.

The power supply circuit 50 can generate voltages required for driving the display panel 10 from the main power applied from the system board and supply the voltages to the display panel 10. For example, the power supply circuit 50 can generate a high-potential voltage VDD and a low-potential voltage VSS for driving the light-emitting elements LD of the display panel 10 from the main power and supply the high-potential voltage VDD and the low-potential. voltage VSS to the high-potential voltage line VDDL and the low-potential voltage line VSSL of the display panel 10. In addition, the power supply circuit 50 can generate and supply driving voltages for driving the driving circuit 20 and the scan driving unit 30 from the main power.

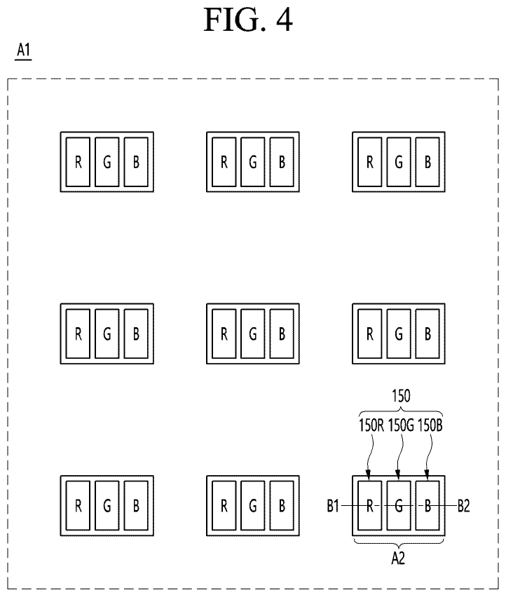

FIG. 4 is an enlarged view of the first panel area in the display device of FIG. 3.

Referring to FIG. 4, the display device 100 of the embodiment can be manufactured by mechanically and electrically connecting a plurality of panel areas such as the first panel area A1 by tiling.

The first panel area A1 may comprise a plurality of semiconductor light-emitting elements 150 disposed for each unit pixel (PX of FIG. 2).

For example, the unit pixel PX may comprise a first sub-pixel PX1, a second sub-pixel PX2, and a third sub-pixel PX3. For example, a plurality of red semiconductor light-emitting elements 150R may be disposed in the first sub-pixel PX1, a plurality of green semiconductor light-emitting elements 150G may be disposed in the second sub-pixel PX2, and a plurality of blue semiconductor light-emitting elements 150B may be disposed in the third sub-pixel PX3. The unit pixel PX may further comprise a fourth sub-pixel in which no semiconductor light-emitting elements are disposed, but is not limited thereto.

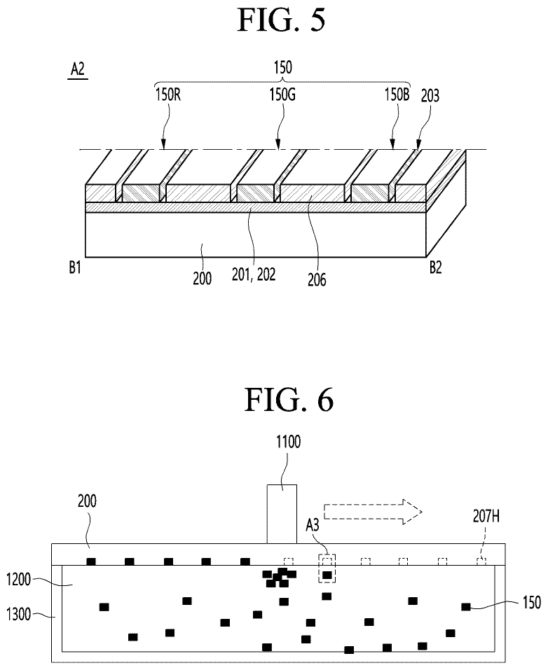

FIG. 5 is an enlarged view of the A2 area of FIG. 4.

Referring to FIG. 5, the display device 100 of the embodiment may comprise a substrate 200, assembling wirings 201 and 202, an insulating layer 206, and a plurality of semiconductor light-emitting elements 150. More components may be included.

The assembling wiring may comprise a first assembling wiring 201 and a second assembling wiring 202 that are spaced apart from each other. The first assembling wiring 201 and the second assembling wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited thereto, a red semiconductor light-emitting element 150, a green semiconductor light-emitting element 150G, and a blue semiconductor light-emitting element 150B to form a unit pixel (sub-pixel), and may also comprise a red phosphor and a green phosphor to implement red and green, respectively,

The substrate 200 may be a support member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in a display panel, and may also function as an assembly substrate when self-assembling a light-emitting element.

The substrate 200 may be a backplane equipped with circuits, such as transistors ST and DT, capacitors Cst, signal wiring, etc., within the sub-pixels PX1, PX2, and PX3 illustrated in FIGS. 2 and 3, but is not limited thereto.

The insulating layer 206 may comprise an organic material having insulation and flexibility, such as polyimide, PAC, PEN, PET, polymer, etc., or an inorganic material, such as silicon oxide (SiO₂) or silicon nitride series (SiNₓ), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be a conductive adhesive layer, such as an anisotropic conductive film (ACF), an anisotropic conductive medium, a solution comprising conductive particles, etc. The conductive adhesive layer may be a layer that is electrically conductive in a vertical direction relative to the thickness, but electrically insulating in a horizontal direction relative to the thickness.

The insulating layer 206 may comprise an assembly hole 203 for inserting the semiconductor light-emitting element 150. Therefore, during self-assembly, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, each of the red semiconductor light-emitting element, the green semiconductor light-emitting element, and the blue semiconductor light-emitting element may have a different shape, and may have an assembly hole 203 having a shape corresponding to each of the shapes of these semiconductor light-emitting elements. For example, the assembly hole 203 may comprise a first assembly hole for assembling a red semiconductor light-emitting element, a second assembly hole for assembling a green semiconductor light-emitting element, and a third assembly hole for assembling a blue semiconductor light-emitting element. For example, the red semiconductor light-emitting element may have a circular shape, the green semiconductor light-emitting element may have a first oval shape having a first short axis and a second long axis, and the blue semiconductor light-emitting element may have a second oval shape having a second short axis and a second long axis, but is not limited thereto. The second long axis of the oval shape of the blue semiconductor light-emitting element may be greater than the second long axis of the oval shape of the green semiconductor light-emitting element, and the second short axis of the oval shape of the blue semiconductor light-emitting element may be smaller than the first short axis of the oval shape of the green semiconductor light-emitting element.

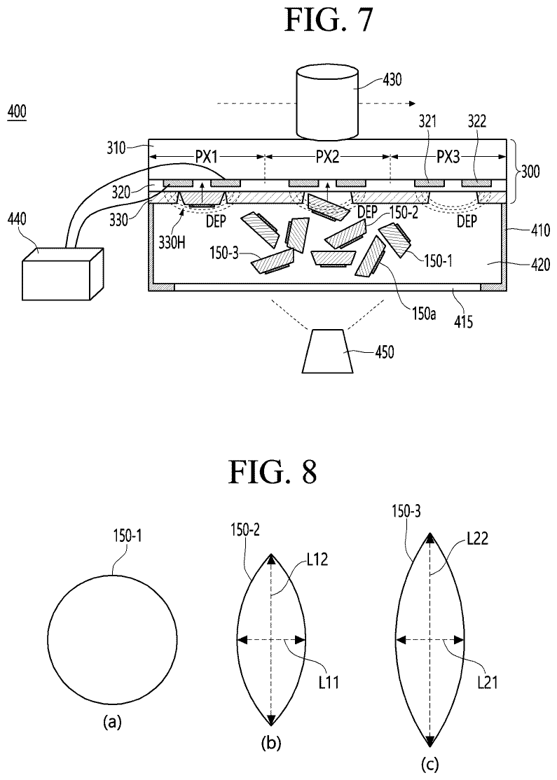

Meanwhile, the method of mounting the semiconductor light-emitting element 150 on the substrate 200 may comprise, for example, a self-assembly method (FIG. 6) and a transfer method.

FIG. 6 is a drawing showing an example in which a light-emitting element according to an embodiment is assembled on a substrate by a self-assembly method.

Based on FIG. 6, an example of assembling a semiconductor light-emitting element according to an embodiment into a display panel by a self-assembly method using an electromagnetic field will be described.

The assembly substrate 200 described below can also function as a panel substrate 200a in a display device after assembling the light-emitting element, but the embodiment is not limited thereto.

Referring to FIG. 6, the semiconductor light-emitting element 150 can be put into a chamber 1300 filled with a fluid 1200, and the semiconductor light-emitting element 150 can be moved to the assembly substrate 200 by a magnetic field generated from the assembly device 1100. At this time, the light-emitting element 150 adjacent to the assembly hole 207H of the assembly substrate 200 can be assembled into the assembly hole 207H by the DEP force caused by the electric field of the assembling wirings. The fluid 1200 can be water such as ultrapure water, but is not limited thereto. The chamber can be called a tank, a container, a vessel, etc.

After the semiconductor light-emitting element 150 is put into the chamber 1300, the assembly substrate 200 may be disposed on the chamber 1300. According to an embodiment, the assembly substrate 200 may be put into the chamber 1300.

The semiconductor light-emitting element 150 may be implemented as a vertical-type semiconductor light-emitting element, but is not limited thereto, and a lateral-type light-emitting element may be employed.

After the assembly substrate 200 is disposed in the chamber, an assembly device 1100 that applies a magnetic field may move along the assembly substrate 200. The assembly device 1100 may be a permanent magnet or an electromagnet.

The assembly device 1100 may move in contact with the assembly substrate 200 in order to maximize the area affected by the magnetic field within the fluid 1200. According to an embodiment, the assembly device 1100 may comprise a plurality of magnetic bodies or may comprise magnetic bodies having a size corresponding to that of the assembly substrate 200. In this case, the movement distance of the assembly device 1100 may be limited within a predetermined range.

The semiconductor light-emitting element 150 in the chamber 1300 may move toward the assembly device 1100 and the assembly substrate 200 by the magnetic field generated by the assembly device 1100.

The semiconductor light-emitting element 150 may enter the assembly hole 207H and be fixed by the DEP force formed by the electric field between the assembling wirings 201 and 202 while moving toward the assembly device 1100.

Specifically, the first and second assembling wirings 201 and 202 form an electric field by the AC power source, and the DEP force may be formed between the assembling wirings 201 and 202 by this electric field. The semiconductor light-emitting element 150 may be fixed to the assembly hole 207H on the assembly substrate 200 by this DEP force.

At this time, a predetermined solder layer (not shown) may be formed between the light-emitting element 150 assembled on the assembly hole 207H of the assembling substrate 200 and the assembling wiring 201 and 202 to improve the bonding strength of the light-emitting element 150.

In addition, a molding layer (not shown) may be formed on the assembly hole 207H of the assembling substrate 200 after assembly. The molding layer may be a transparent resin or a resin comprising a reflective material or a scattering material.

By the self-assembly method using the electromagnetic field described above, the time required for each of the plurality of semiconductor light-emitting elements to be assembled on the substrate can be drastically shortened, so that a large-area, high-pixel display can be implemented more quickly and economically.

Meanwhile, although not shown, a Vdd line may be disposed between the first assembling wiring 201 and the second assembling wiring 202 to be used as an electrode wiring for electrically contacting the semiconductor light-emitting element 150.

However, as the semiconductor light-emitting element 150 is miniaturized, the gap between the first assembling wiring 201 and the second assembling wiring 202 also becomes narrower, and when the gap between the first assembling wiring 201 and the second assembling wiring 202 becomes narrower, a problem may occur in which the first assembling wiring 201 or the second assembling wiring 202 is electrically shorted with the Vdd line.

[symbol]

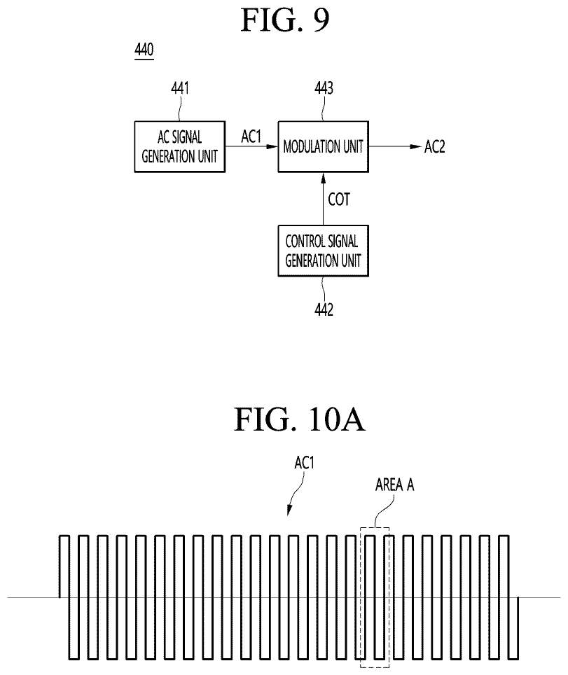

Hereinafter, various embodiments for solving the above-described problem will be described with reference to FIGS. 7 to 21. Any description omitted below can be easily understood from the descriptions described above with respect to FIGS. 1 to 6 and the corresponding drawings.

FIG. 7 illustrates a device for manufacturing a display device according to an embodiment.

Referring to FIG. 7, a device 400 for manufacturing a display device according to an embodiment may comprise a chamber 410, a magnetic member 430, and a signal supply device 440. The chamber 410 and the magnetic member 430 may be identical to the chamber 1300 and the assembly device 1100 illustrated in FIG. 6, respectively.

The chamber 410 may be filled with a fluid 420. A plurality of semiconductor light-emitting elements 150-1, 150-2, and 150-3 that emit different color light may be put into the fluid 420.

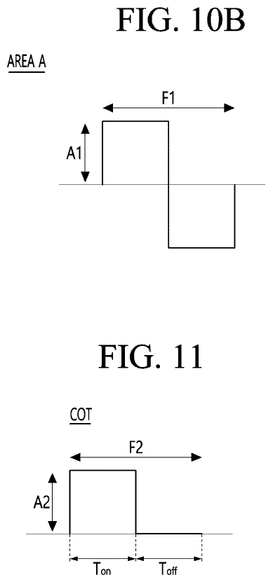

The plurality of semiconductor light-emitting elements 150-1, 150-2, and 150-3 may have various shapes, as illustrated in FIG. 8. The plurality of semiconductor light-emitting elements may comprise a plurality of first semiconductor light-emitting elements 150-1, a plurality of second semiconductor light-emitting elements 150-2, and a plurality of third semiconductor light-emitting elements 150-3. The first semiconductor light-emitting element 150-1 can emit a first color light, the second semiconductor light-emitting element 150-2 can emit a second color light, and the third semiconductor light-emitting element 150-3 can emit a third color light. The first color light may comprise red light, the second color light may comprise green light, and the third color light may comprise blue light, but is not limited thereto.

In FIG. 8, the various shapes of the semiconductor light-emitting elements 150-1, 150-2, and 150-3 may be shapes viewed from above. The first semiconductor light-emitting element 150-1 may have a circular shape (FIG. 8A), the second semiconductor light-emitting element 150-2 may have a first oval shape (FIG. 8B), and the third semiconductor light-emitting element 150-3 may have a second oval shape (FIG. 8C), but is not limited thereto. In this case, the length L22 of the major axis of the second oval shape may be greater than the length L12 of the major axis of the first oval shape. In addition, the length L21 of the minor axis of the second oval shape may be less than the length L11 of the minor axis of the first oval shape, but is not limited thereto. In this case, the areas of each of the first semiconductor light-emitting element 150-1, the second semiconductor light-emitting element 150-2, and the third semiconductor light-emitting element 150-3 may be the same, but is not limited thereto.

The thickness (or height) of each of the first semiconductor light-emitting element 150-1, the second semiconductor light-emitting element 150-2, and the third semiconductor light-emitting element 150-3 may be the same, but is not limited thereto.

Meanwhile, a viewpoint 415 may be installed in a portion of the lower side of the chamber 410 so as to view the inside of the chamber 410. The viewpoint 415 may be glass, but is not limited thereto. A camera 450 may be installed under the chamber 410 so that the situation inside the chamber 410 can be monitored through the viewpoint 415. That is, the camera 450 can be used to manage whether the plurality of semiconductor light-emitting elements 150-1, 150-2, and 150-3 inside the chamber 410 are moved appropriately or whether the plurality of semiconductor light-emitting elements 150-1, 150-2, and 150-3 are correctly assembled on the display substrate 300 without defects. The display substrate 300 may be a substrate for assembling the plurality of semiconductor light-emitting elements 150-1, 150-2, and 150-3 using a self-assembly method, and through a post-process, additional components can be further formed or installed on the display substrate on which the plurality of semiconductor light-emitting elements 150-1, 150-2, and 150-3 are assembled, so that a display device can be manufactured.

A magnetic member 430 may be positioned on the chamber 410. The magnetic member 430 may move in a predetermined direction, so that a plurality of semiconductor light-emitting elements 150-1, 150-2, and 150-3 in the fluid 420, which are affected by the magnetic field of the magnetic member 430, may move along the moving direction of the magnetic member 430. For example, the predetermined direction may be various, such as a rotational direction, a zigzag direction, etc. The semiconductor light-emitting elements 150-1, 150-2, and 150-3 may comprise a magnetic layer 150a so as to be magnetized by the magnetic field of the magnetic member 430. Although the drawing illustrates that the magnetic layer 150a is disposed on the upper side of the semiconductor light-emitting elements 150-1, 150-2, and 150-3, it may also be disposed on the lower side of the semiconductor light-emitting elements 150-1, 150-2, and 150-3.

A display substrate 300 may be installed on the upper side of the chamber 410. When the display substrate 300 is installed on the upper side of the chamber 410, the lower side of the substrate may be in contact with the fluid 420.

The display substrate 300 may be a substrate for simultaneously assembling the first semiconductor light-emitting element 150-1, the second semiconductor light-emitting element 150-2, and the third semiconductor light-emitting element 150-3.

The display substrate 300 may comprise a substrate 310, an insulating layer 320, assembling wirings 321 and 322, and a partition wall 330, but more components may also be included. The substrate 310 may serve to support components disposed thereon. The insulating layer 320 may insulate the first assembling wiring 321 and the second assembling wiring 322 and may allow for an electrophoretic force DEP to be formed more easily. The first assembling wiring 321 and the second assembling wiring 322 may be disposed in each of the first sub-pixel PX1, the second sub-pixel PX2, and the third sub-pixel PX3.

The partition wall 330 may have a plurality of assembly holes 330H. For example, each of the first sub-pixel PX1, the second sub-pixel PX2, and the third sub-pixel PX3 may have at least one assembly hole 330H. The assembly hole 330H can guide the semiconductor light-emitting elements 150-1, 150-2, and 150-3 to be inserted. The depth of the assembly hole 330H can be equal to or smaller than the thickness of the semiconductor light-emitting elements 150-1, 150-2, and 150-3.

The assembly hole 330H can have a shape corresponding to the shape of the semiconductor light-emitting elements 150-1, 150-2, and 150-3. When the first semiconductor light-emitting element 150-1 is assembled into the first assembly hole, the second semiconductor light-emitting element 150-2 is assembled into the second assembly hole, and the third semiconductor light-emitting element 150-3 is assembled into the third assembly hole, when viewed from above, the first assembly hole may have a shape corresponding to the shape of the first semiconductor light-emitting element 150-1, that is, a circular shape, the second assembly hole may have a shape corresponding to the shape of the second semiconductor light-emitting element 150-2, that is, a first oval shape, and the third assembly hole may have a shape corresponding to the shape of the third semiconductor light-emitting element 150-3, that is, a second oval shape. The sizes of the first assembly hole, the second assembly hole, and the third assembly hole may be greater than the sizes of the first semiconductor light-emitting element 150-1, the second semiconductor light-emitting element 150-2, and the third semiconductor light-emitting element 150-3, respectively.

The assembly process of semiconductor light-emitting elements 150-1, 150-2 and 150-3 in the manufacturing device 400 of the display device configured as described above is described.

First, a plurality of first semiconductor light-emitting elements 150-1, a plurality of second semiconductor light-emitting elements 150-2 and a plurality of third semiconductor light-emitting elements 150-3 can be put into a fluid 420 in a chamber 410. Then, a display substrate 300 can be installed on the upper side of the chamber 410, and a magnetic member 430 can be initialized to a predetermined position.

The magnetic member 430 can move in a predetermined direction, and an alternating current signal can be supplied from a signal supply device 440 to the first assembling wiring 321 and the second assembling wiring 322 of the display substrate 300. A plurality of first semiconductor light-emitting elements 150-1, a plurality of second semiconductor light-emitting elements 150-2, and a plurality of third semiconductor light-emitting elements 150-3 within the fluid 420 can move along the movement direction of the magnetic member 430. That is, a plurality of first semiconductor light-emitting elements 150-1, a plurality of second semiconductor light-emitting elements 150-2, and a plurality of third semiconductor light-emitting elements 150-3 can move parallel to the lower side of the display substrate 300.

A dielectrophoretic force DEP can be formed between the first assembling wiring 321 and the second assembling wiring 322 by an alternating current signal supplied from the signal. supply device 440. Since the first assembling wiring 321 and the second assembling wiring 322 are disposed in the first sub-pixel PX1, the second sub-pixel PX2, and the third sub-pixel PX3, respectively, a dielectrophoretic force DEP can be formed in the first sub-pixel PX1, the second sub-pixel PX2, and the third sub-pixel PX3, respectively. Accordingly, the plurality of first semiconductor light-emitting elements 150-1, the plurality of second semiconductor light-emitting elements 150-2, and the plurality of third semiconductor light-emitting elements 150-3, which are moved parallel to the lower side of the display substrate 300, can be inserted into the assembly holes 330H of the first sub-pixel PX1, the second sub-pixel PX2, and the third sub-pixel PX3, respectively, by the dielectrophoretic force DEP formed in the first sub-pixel PX1, the second sub-pixel PX2, and the third sub-pixel PX3, respectively. The first semiconductor light-emitting element 150-1, the second semiconductor light-emitting element 150-2, and the third semiconductor light-emitting element 150-3, which are inserted into the assembly holes of the first sub-pixel PX1, the second sub-pixel PX2, and the third sub-pixel PX3, respectively, can be fixed by dielectrophoretic force DEP.

[symbol]

Meanwhile, as described above, mis-assembly occurs during the assembly process of the semiconductor light-emitting elements 150-1, 150-2, and 150-3. For example, the first semiconductor light-emitting element 150-1 may not be assembled into the first assembly hole. of the first sub-pixel PX1 for correct assembly, but may be assembled into the second assembly hole of the second sub-pixel PX2 or the third assembly hole of the third sub-pixel PX3, resulting in mis-assembly defects. For example, a mis-assembly defect may occur in which the third semiconductor light-emitting element 150-3 is not assembled into the third assembly hole of the third sub-pixel PX3 for correct assembly, but is assembled into the first assembly hole of the first sub-pixel or the second assembly hole of the second sub-pixel PX2.

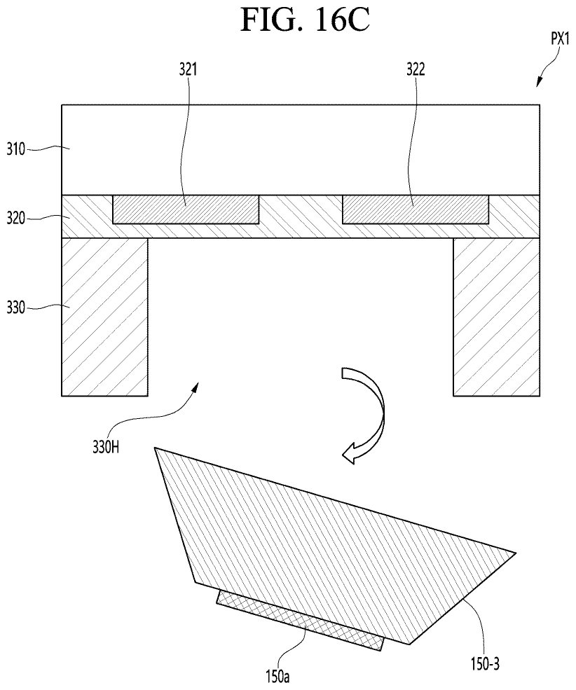

As illustrated in FIG. 15A, when a dielectrophoretic force DEP is formed in the first sub-pixel PX1, the first semiconductor light-emitting element 150-1 may be correctly assembled into the assembly hole 330H of the first sub-pixel PX1.

However, the second semiconductor light-emitting element 150-2 or the third semiconductor light-emitting element 150-3, not the first semiconductor light-emitting element 150-1, may be incorrectly assembled into the first sub-pixel PX1. The second semiconductor light-emitting element 150-2 may have the first oval shape, and the third semiconductor light-emitting element 150-3 may have the second oval shape. In this case, the second semiconductor light-emitting element 150-2 may not be inserted into the assembly hole 330H and may be positioned on the partition wall 330 around the assembly hole 330H (FIG. 15B). In addition, the third semiconductor light-emitting element 150-3 may be inserted into the assembly hole 330H but may be tilted within the assembly bole 330H so that one side of the third semiconductor light-emitting element 150-3 contacts the bottom surface of the assembly hole 330H and the other side contacts the partition wall 330 contacting the assembly hole 330H (FIG. 15C). As illustrated in FIG. 15B, parts of both sides of the second semiconductor light-emitting element 150-2 having the first oval shape contact the upper surface of the partition wall 330 with a small contact area (CA2), and areas other than both sides of the second semiconductor light-emitting element 150-2 do not contact any member. Therefore, the second semiconductor light-emitting element 150-2 or the third semiconductor light-emitting element 150-3 is weakly physically contacted with the display substrate 300 and is only weakly fixed by the dielectrophoretic force DEP.

According to the non-public internal technology, when the first semiconductor light-emitting element 150-1 has a circular shape (FIG. 8a), the second semiconductor light-emitting element 150-2 has a first oval shape (FIG. 8b), and the third semiconductor light-emitting element 150-3 has a second oval shape (FIG. 8c), there are many cases of mis-assembly defects in which the first semiconductor light-emitting element 150-1 or the third semiconductor light-emitting element 150-3 is assembled into the second assembly hole of the second sub-pixel PX2. This is because the first oval shape of the second semiconductor light-emitting element 150-2 has an intermediate shape between the circular shape of the first semiconductor light-emitting element 150-1 and the second oval shape of the third semiconductor light-emitting element 150-3. Since the second assembly hole of the second sub-pixel PX2 has a shape corresponding to the shape of the second semiconductor light-emitting element 150-2, i.e., the first oval shape, the second assembly hole of the second sub-pixel PX2 overlaps with the first semiconductor light-emitting element 150-1 or the third semiconductor light-emitting element as much as with the second semiconductor light-emitting element 150-2, and thus mis-assembly often occurs particularly in the second assembly hole of the second sub-pixel PX2.

Such mis-assembly causes color mixing defects. That is, when the first semiconductor light-emitting element 150-1 or the third semiconductor light-emitting element 150-3, instead of the second semiconductor light-emitting element 150-2, is assembled into the second assembly hole of the second sub-pixel PX2, there is a problem that white is not formed in the unit pixels constituting the first sub-pixel PX1, the second sub-pixel PX2, and the third sub-pixel PX3 when implementing the display, so that the desired color image is not implemented.

The embodiment has as its main technical task to solve this problem. That is, the embodiment can prevent color mixing defects and improve the correct assembly rate by removing the incorrectly-assembled semiconductor light-emitting element from the corresponding assembly hole and assembling the semiconductor light-emitting element that matches the corresponding assembly hole into the corresponding assembly hole.

To this end, the signal supply device 440 can output a modulated second alternating current signal AC2. The above-described modulated second alternating current signal AC2 may form a dielectrophoretic force DEP between the first assembling wiring 321 and the second assembling wiring 322 of each of the first sub-pixel PX1, the second sub-pixel PX2, and the third sub-pixel PX3.

In an embodiment, the modulated second alternating current signal AC2 may change the dielectrophoretic force DEP to attach and detach the first semiconductor light-emitting element 150-1, the second semiconductor light-emitting element 150-2, and the third semiconductor light-emitting element 150-3 contained in the fluid 420 to the plurality of assembly holes 330H of the display substrate 300, respectively.

According to the non-public internal technology, the dielectrophoretic force DEP is constantly formed between the first assembling wiring 321 and the second assembling wiring 322. Therefore, if the first semiconductor light-emitting element 150-1, the second semiconductor light-emitting element 150-2, or the third semiconductor light-emitting element 150-3 is incorrectly-assembled in the corresponding assembly hole, the first semiconductor light-emitting element 150-1, the second semiconductor light-emitting element 150-2, or the third semiconductor light-emitting element 150-3 may not be detached from the corresponding assembly hole and is manufactured as a display device, so that color mixing defects may not be prevented.

In contrast, according to the embodiment, the signal supply device 440 supplies the modulated second alternating current signal AC2 to the first assembling wiring 321 and the second assembling wiring 322 of each of the first sub-pixel PX1, the second sub-pixel PX2, and the third sub-pixel PX3, thereby periodically changing the dielectrophoretic force DEP formed between the first assembling wiring 321 and the second assembling wiring 322.

Therefore, even if the first semiconductor light-emitting element 150-1, the second semiconductor light-emitting element 150-2, or the third semiconductor light-emitting element 150-3 is incorrectly-assembled in the corresponding assembly hole 330H, the first semiconductor light-emitting element 150-1, the second semiconductor light-emitting element 150-2, or the third semiconductor light-emitting element 150-3 can be detached from the corresponding assembly hole 330H by the periodically changing dielectrophoretic force DEP. Thereafter, a semiconductor light-emitting element that matches the corresponding assembly hole 330H can be correctly assembled in the corresponding assembly hole 330H from which the first semiconductor light-emitting element 150-1, the second semiconductor light-emitting element 150-2, or the third semiconductor light-emitting element 150-3 was detached. Therefore, color mixing defects due to incorrect assembly of semiconductor light-emitting elements can be prevented, the correct assembly rate can be improved, and the reliability of the product can be enhanced.

[symbol]

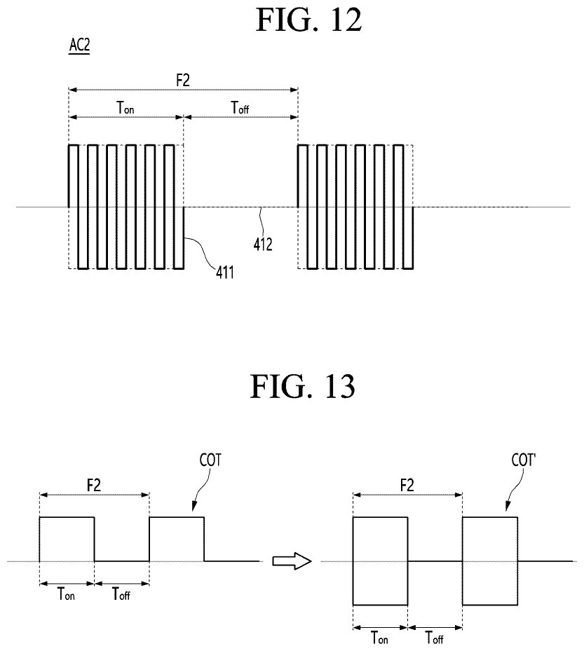

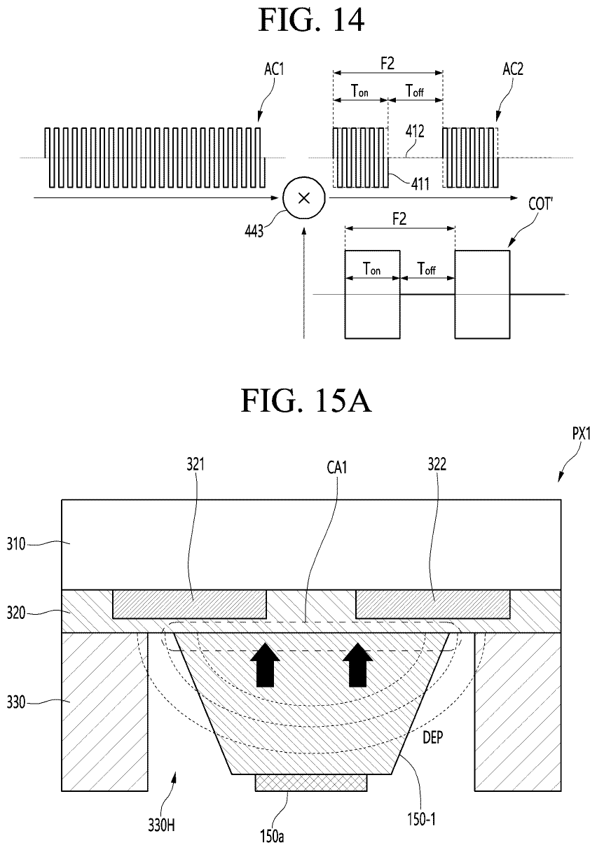

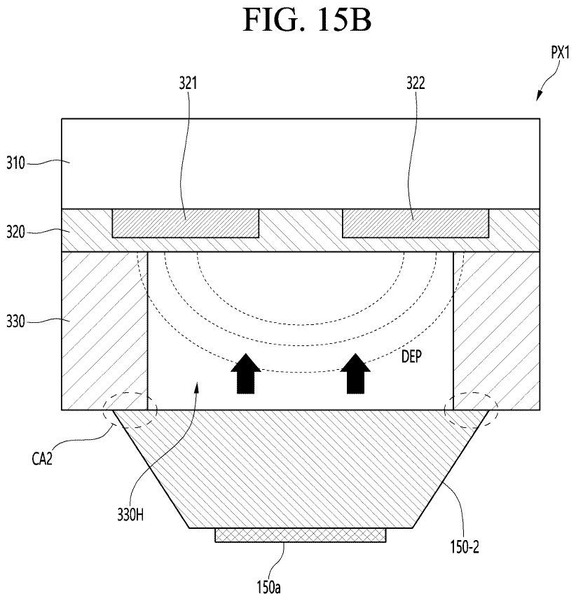

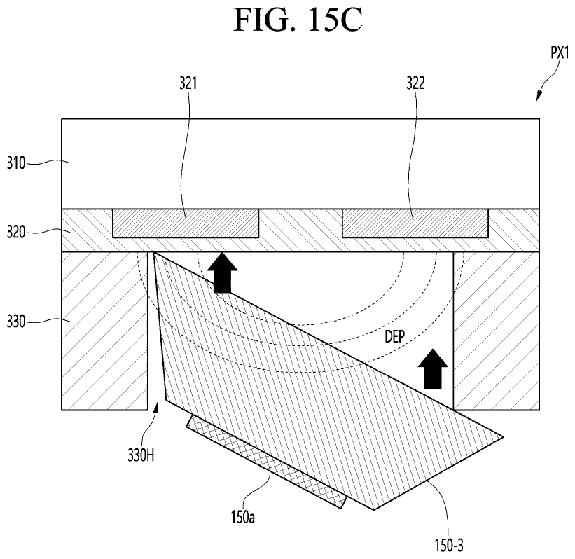

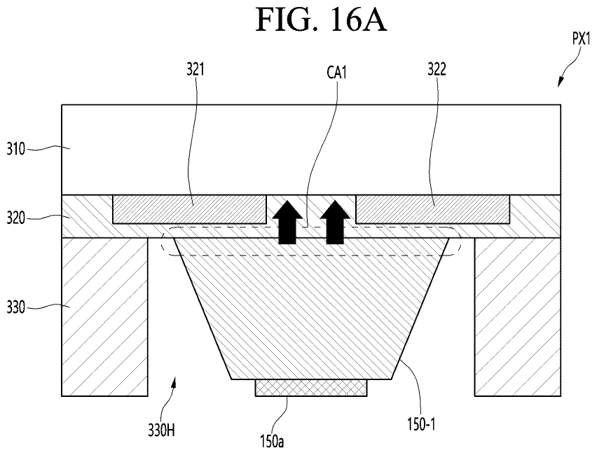

Hereinafter, the signal supply device of the embodiment will be described in detail with reference to FIGS. 9 to 13. FIG. 9 is a block diagram illustrating the signal supply device of FIG. 7. FIG. 10A illustrates a waveform of a first alternating current signal. FIG. 10B is an enlarged view of area A of FIG. 10A. FIG. 11 illustrates a waveform of a control signal having one period. FIG. 12 illustrates a waveform of a second alternating current signal AC2. FIG. 13 illustrates a modulation pattern of the control signal.

Referring to FIG. 9, the signal supply device 440 may comprise an alternating current signal generation unit 441, a control signal generation unit 442, and a modulation unit 443.

The alternating current signal generation unit 441 may generate a first alternating current signal AC1. As illustrated in FIG. 10A, the first alternating current signal AC1 may have a positive (+) signal and a negative (−) signal with one period F1 and may have an amplitude A1. For example, the frequency of the first alternating current signal AC1 may be several kHz to several hundred kHz. The amplitude A1 is a factor related to the strength of the dielectrophoretic force DEP and may be several V to several tens of V.

The control signal generation unit 442 may generate a control signal COT. The control signal COT may be a digital signal or an analog signal. The control signal COT may be a signal that controls the generation of the second alternating current signal AC2, as will be described later. For example, as illustrated in FIG. 11, the control signal COT may have an ON section Ton and an OFF section Toff with one period F2 and may have an amplitude A2. The amplitude A2 may be a factor that determines the strength of the second alternating current signal AC2. The frequency of the control signal COT may be several tens of Hz to several hundred Hz. The ON section1 Ton may have a signal with a level greater than 0 (hereinafter referred to as a positive level signal), and the OFF section Toff may have 0. In other words, the OFF section Toff may have a signal with a level of 0 (hereinafter referred to as a negative level signal). The control signal COT may have a waveform periodically as shown in FIG. 11.

The modulation unit 443 may modulate the first alternating current signal AC1 of the alternating current signal generation unit 441 into the second alternating current signal AC2 according to the control signal COT of the control signal generation unit 442.

The waveform of the second alternating current signal AC2 may have a shape corresponding to the shape of the waveform of the control signal COT, but is not limited thereto.

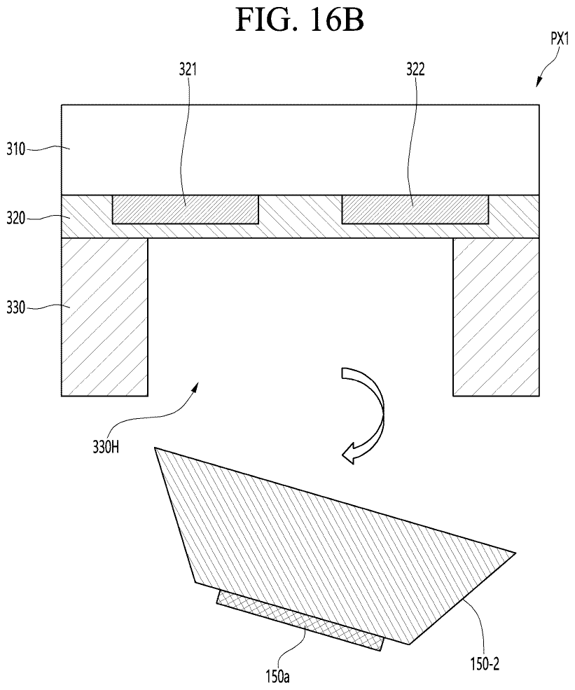

For example, the modulation unit 443 can modulate the control signal COT into a symmetrical waveform symmetrical to the time axis (COT′ in FIG. 14), and generate a waveform corresponding to the modulated symmetrical waveform COT′ among the waveforms of the first alternating current signal AC1 as a waveform of the second alternating current signal AC2.

As illustrated in FIG. 13, when the control signal COT is input to the modulation unit 443, the modulation unit 443 can modulate the waveform of the control signal COT so that it bas symmetry with respect to the time axis. For example, in the ON section Ton of the control signal COT, a positive level signal can be inverted to the time axis to generate a negative level signal, and the positive level signal and the negative level signal can be added. Accordingly, in the ON section Ton, a positive level signal and a negative level signal can be symmetrical to the time axis. For example, in the OFF section Toff of the control signal COT, a 0 level signal can be maintained as a 0 level signal. Accordingly, the modulated control signal COT can have a waveform having a positive level signal and a negative level signal symmetrical to the time axis in the ON section Ton and a zero level signal in the OFF section Toff.

[symbol]

### First Embodiment

FIG. 14 illustrates a pattern of modulating a first alternating current signal AC1 into a second alternating current signal according to a first embodiment.

The modulation unit 443 may comprise a multiplier 445, etc., as illustrated in FIG. 14, but is not limited thereto.

The multiplier 445 may generate a waveform corresponding to the modulated symmetrical waveform COT′ among the waveforms of the first alternating current signal AC1 as a waveform of the second alternating current signal AC2. That is, the symmetrical waveform COT′ in which the waveform of the control signal COT is modulated can have a first waveform corresponding to the ON section Ton and a second waveform corresponding to the OFF section Toff. In this case, among the waveforms of the first alternating current signal AC1, the waveform of the first alternating current signal AC1 corresponding to the first waveform is maintained along the shape of the first waveform and has the waveform of the second-first alternating current signal 411, and among the waveforms of the first alternating current signal AC1, the waveform of the first alternating current signal AC1 corresponding to the second waveform can have the waveform of the second-second alternating current signal 412 having a 0 level. The waveform of the second-first alternating current signal 411 can have a rectangular waveform. For example, the second-first alternating current signal 411 comprises the first alternating current signal AC1, and the second-second alternating current signal 412 can comprise a 0 level signal.

For example, when the first waveform of the modulated control signal COT′ is a rectangular waveform, the second-first alternating current signal 411 can have a rectangular file. For example, if the first waveform of the modulated control signal COT′ is a triangle waveform, the second-first alternating current signal 411 may have a triangle waveform. For example, if the first waveform of the modulated control signal COT′ is a sine waveform, the second-first alternating current signal 411 may have a sine waveform. The sine waveform may be called a round waveform.

Meanwhile, the modulation unit 443 can supply the modulated second alternating current signal AC2 having the second-first alternating current signal 411 and the second-second alternating current signal 412 with one period F2 to the first assembling wiring 321 and the second assembling wiring 322 of the first sub-pixel PX1, the second sub-pixel PX2, and the third sub-pixel PX3 of the display substrate 300, respectively. Accordingly, the dielectrophoretic force DEP formed between the first assembling wiring 321 and the second assembling wiring 322 of the first sub-pixel PX1, the second sub-pixel PX2, and the third sub-pixel PX3, respectively, can be periodically changed.

For example, a dielectrophoretic force DEP may be formed by the second-first alternating current signal 411 of the second alternating current signal AC2 supplied during the ON section Ton of one period F2, so that each of the first semiconductor light-emitting element 150-1, the second semiconductor light-emitting element 150-2, and the third semiconductor light-emitting element 150-3 can be assembled into the assembly hole 330H of the first sub-pixel PX1, the second sub-pixel PX2, and the third sub-pixel PX3, respectively.

For example, a dielectrophoretic force DEP is not formed by the second-second alternating current signal 412 of the second alternating current signal AC2. That is, the generation of a dielectrophoretic force DEP formed by the second-first alternating current signal 411 can be stopped by the second-second alternating current signal 412 of the second alternating current signal AC2. For example, since the second-second alternating current signal 412 of the second alternating current signal AC2 is a 0-level signal, no signal is supplied from the modulation unit 443 to the display substrate 300 during the OFF section Toff of one period F2. Accordingly, the dielectrophoretic force DEP formed between the first assembling wiring 321 and the second assembling wiring 322 of each of the first sub-pixel PX1, the second sub-pixel PX2, and the third sub-pixel PX3 may be reduced and eliminated. If a semiconductor light-emitting element is incorrectly-assembled into the assembly hole 330H of each of the first sub-pixel PX1, the second sub-pixel PX2, or the third sub-pixel PX3 during the ON section Ton, the incorrectly-assembled semiconductor light-emitting element may be detached from the corresponding assembly hole 330H during the OFF section Toff. That is, since the dielectrophoretic force DEP disappears during the OFF section Toff, the semiconductor light-emitting element may not be fixed, and thus the corresponding semiconductor light-emitting element may be detached from the corresponding hole.

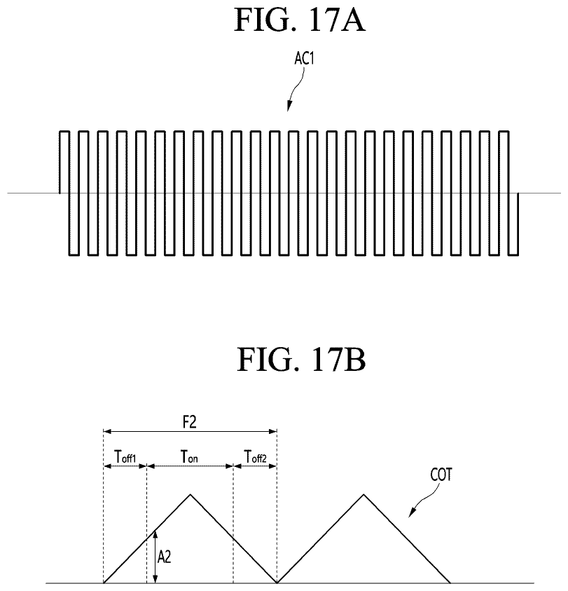

As illustrated in FIG. 16B and FIG. 16C, the second semiconductor light-emitting element 150-2 or the third semiconductor light-emitting element 150-3 incorrectly-assembled in the assembly hole 330H of the first sub-pixel PX1 may be detached from the corresponding assembly hole 330H because a dielectrophoretic force DEP is not formed during the OFF section Toff. Since the shape of the second semiconductor light-emitting element 150-2 or the shape of the third semiconductor light-emitting element 150-3 is different from the shape of the first sub-pixel PX1, the second semiconductor light-emitting element 150-2 or the third semiconductor light-emitting element 150-3 may not be completely assembled in the corresponding assembly hole 330H but may partially contact the upper surface of the partition 330 (FIG. 16B) or may be assembled tilted in the assembly hole 330H (FIG. 16B). In this case, since a low level or 0 level signal is supplied during the OFF section Toff of the second alternating current signal AC2 and the dielectrophoretic force DEP does not exist, the second semiconductor light-emitting element 150-2 or the third semiconductor light-emitting element 150-3 can easily be detached from the assembly hole 330H of the first sub-pixel PX1.

Meanwhile, as illustrated in FIG. 16A, the first semiconductor light-emitting element 150-1 assembled in the assembly hole 330H of the first sub-pixel PX1 is not detached from the corresponding assembly hole 330H even if the dielectrophoretic force DEP is not formed during the OFF section Toff. That is, since the first semiconductor light-emitting element 150-1 and the bottom surface of the assembly hole 330H of the first sub-pixel PX1 are in contact with a large contact area (CA1), a van der Waals force acts between the first semiconductor light-emitting element 150-1 and the bottom surface of the assembly hole 330H of the first sub-pixel PX1, thereby preventing the detachment of the first semiconductor light-emitting element 150-1.

Even if a magnetic field of the magnetic member 430 is generated, since the van der Waals force acting between the first semiconductor light-emitting element 150-1 and the bottom surface of the assembly hole 330H of the first sub-pixel PX1 is greater than the force of the magnetic field formed by the magnetic member 430, the first semiconductor light-emitting element 150-1 can be fixed to the assembly hole 330H without being detached from the assembly hole 330H of the first sub-pixel PX1.

Since the second alternating current signal AC2 having the second-first alternating current signal 411 and the second-second alternating current signal 412 is supplied to the first sub-pixel PX1, the second sub-pixel PX2, and the third sub-pixel PX3, respectively, through the first assembling wiring 321 and the second assembling wiring 322, even if the semiconductor light-emitting element incorrectly-assembled in the corresponding assembly hole 330H is not detached by the second-second alternating current signal 412 within one period F2, the semiconductor light-emitting element incorrectly-assembled can be detached from the corresponding assembly hole 330H by the second-second alternating current signal 412 of the second period, the third period, etc., thereby minimizing the mis-assembly rate and maximizing the correct assembly rate.

[symbol]

### Second Embodiment

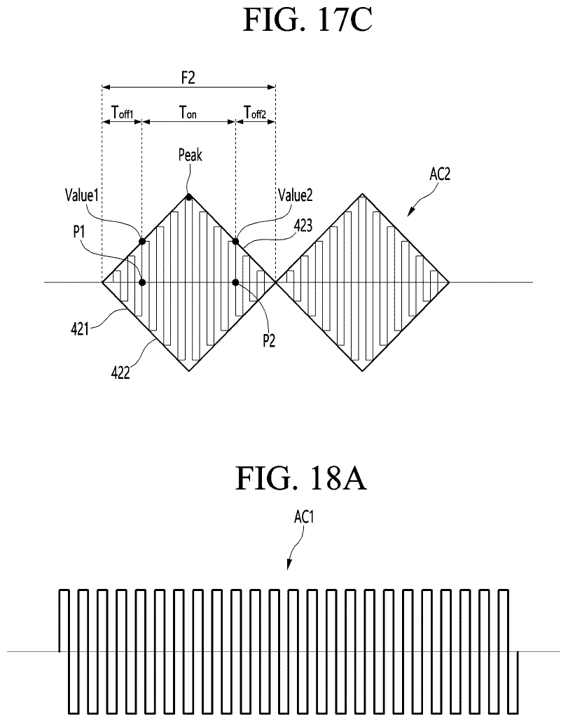

FIG. 17 illustrates a state in which the first alternating current signal AC1 is modulated into the second alternating current signal according to a second embodiment.

Referring to FIG. 9, the signal supply device 440 can generate a second alternating current signal AC2 (FIG. 17C) by modulating the first alternating current signal AC1 (FIG. 17A) using the waveform of the control signal COT (FIG. 17B).

To this end, the control signal generation unit 442 can generate a control signal COT having a triangular waveform.

The control signal COT can be configured as a waveform having a first OFF section Toff1, an ON section Ton, and a second OFF section Toff2 as one period F2. For example, a first control signal in which the amplitude A2 increases linearly from 0 during the first OFF section Toff1 is generated, a second control signal in which the amplitude A2 increases linearly toward a peak value during the ON section Ton and then decreases linearly is generated, and a third control signal in which the amplitude A2 decreases linearly to 0 during the second OFF section Toff2 can be generated.

The modulation unit 443 can modulate the control signal COT into a symmetrical waveform symmetrical to the time axis (COT′ of FIG. 14), and generate a waveform corresponding to the modulated symmetrical waveform COT′ among the waveforms of the first alternating current signal AC1 as a waveform of the second alternating current signal AC2. Accordingly, each of the first to third control signals can be modulated into a symmetrical waveform COT′ symmetrical to the time axis for each of the first OFF section Toff1, the ON section Ton, and the second OFF section Toff2. Thereafter, the waveform of the first alternating current signal AC1 corresponding to the symmetrical waveform COT′ of each of the first to third control signals can be generated as a waveform of the second alternating current signal AC2.

Therefore, as illustrated in FIG. 17C, the second alternating current signal AC2 may have a second-first alternating current signal 421 corresponding to the first OFF section Toff1, a second-second alternating current signal 422 corresponding to the ON section Ton, and a second-third alternating current signal 423 corresponding to the second OFF section Toff2. In other words, the second alternating current signal AC2 may comprise a first alternating current signal AC1 corresponding to a symmetrical waveform (COT′ in FIG. 14) symmetrically modulated with a control signal COT on the time axis.

The second alternating current signal AC2 illustrated in FIG. 17C may be supplied to the first assembling wiring 321 and the second assembling wiring 322 of each of the first sub-pixel PX1, the second sub-pixel PX2, and the third sub-pixel PX3 of the display substrate 300 illustrated in FIG. 7, so that the dielectrophoretic force DEP formed between the first assembling wiring 321 and the second assembling wiring 322 can be periodically changed.

The second-first alternating current signal 421 can increase in amplitude A2 from 0 to a first value Value1, the second-second alternating current signal 422 can increase in amplitude A2 from the first value Value1 to a peak value (Peak), and then decrease from the peak value to a second value Value2, and the second-third alternating current signal 423 can decrease in amplitude A2 from the second value Value2 to 0. That is, the second alternating current signal AC2 may comprise the first alternating current signal AC1 corresponding to the symmetrical waveform (COT′ of FIG. 14) symmetrically modulated with the control signal COT on the time axis.

The second alternating current signal AC2 illustrated in FIG. 17C may be supplied to the first assembling wiring 321 and the second assembling wiring 322 of each of the first sub-pixel. PX1, the second sub-pixel PX2, and the third sub-pixel PX3 of the display substrate 300 illustrated in FIG. 7, so that the dielectrophoretic force DEP formed between the first assembling wiring 321 and the second assembling wiring 322 may be periodically changed.

The dielectrophoretic force DEP may be formed during a specific section between the first point P1 corresponding to the first value Value1 and the second point P2 corresponding to the second value Value2, and the dielectrophoretic force DEP may not be formed before the first point P1 or after the second point P2.

For example, by the second-second alternating current signal 422 supplied during the ON period Ton of one period F2, the dielectrophoretic force DEP may be formed to the maximum between the first assembling wiring 321 and the second assembling wiring 322, so that the first semiconductor light-emitting element 150-1, the second semiconductor light-emitting element 150-2, and the third semiconductor light-emitting element 150-3 can be assembled into the assembly holes 330H of each of the first sub-pixel PX1, the second sub-pixel PX2, and the third sub-pixel PX3.

For example, the dielectrophoretic force DEP between the first assembling wiring 321 and the second assembling wiring 322 may be reduced by the second-first alternating current signal 421 supplied during the first OFF section Toff1 of one period F2 or the second-third alternating current signal 423 supplied during the second OFF section Toff2, so that the first semiconductor light-emitting element 150-1, the second semiconductor light-emitting element 150-2 and/or the third semiconductor light-emitting element 150-3, which are incorrectly-assembled in the assembly hole 330H of the first sub-pixel PX1, the second sub-pixel PX2 and/or the third sub-pixel PX3 during the ON section Ton, can be disassembled, i.e., detached.

Meanwhile, a second alternating current signal AC2 having a second-first alternating current signal 421, a second-second alternating current signal 422, and a second-third alternating current signal 423 may be supplied to the first assembling wiring 321 and the second assembling wiring 322 of each of the first sub-pixel PX1, the second sub-pixel PX2, and the third sub-pixel PX3. In this case, if the mis-assembled semiconductor light-emitting element is not detached during the second OFF section Toff2 of the first period during the ON section Ton of the first period, the mis-assembled semiconductor light-emitting element may be detached from the corresponding assembly hole 330H during the first OFF section Toff1 and the second OFF section Toff2 of each period, such as the second period, the third period, and the fourth period, and a semiconductor light-emitting element matching the corresponding assembly hole 330H may be correctly assembled in the corresponding assembly hole 330H during the ON section Ton of the next period.

According to the second embodiment, a second alternating current signal AC2 having a triangular waveform can be generated using a control signal COT having a triangular waveform, and the second alternating current signal AC2 can be supplied to the first assembling wiring 321 and the second assembling wiring 322 of each of the first sub-pixel PX1, the second sub-pixel PX2, and the third sub-pixel PX3. Accordingly, the first semiconductor light-emitting element 150-1, the second semiconductor light-emitting element 150-2, and the third semiconductor light-emitting element 150-3 can be assembled simultaneously on the display substrate 300, and even if the first semiconductor light-emitting element 150-1, the second semiconductor light-emitting element 150-2, and/or the third semiconductor light-emitting element 150-3 is incorrectly-assembled, the dielectrophoretic force DEP can be periodically changed to easily detach them from the corresponding assembly hole 330H.

Therefore, the incorrect assembly rate of the first semiconductor light-emitting element 150-1, the second semiconductor light-emitting element 150-2, and/or the third semiconductor light-emitting element 150-3 can be minimized, thereby maximizing the correct assembly rate, and preventing color mixing due to incorrect assembly of the first semiconductor light-emitting element 150-1, the second semiconductor light-emitting element 150-2, and/or the third semiconductor light-emitting element 150-3, thereby enhancing product reliability.

[symbol]

### Third Embodiment

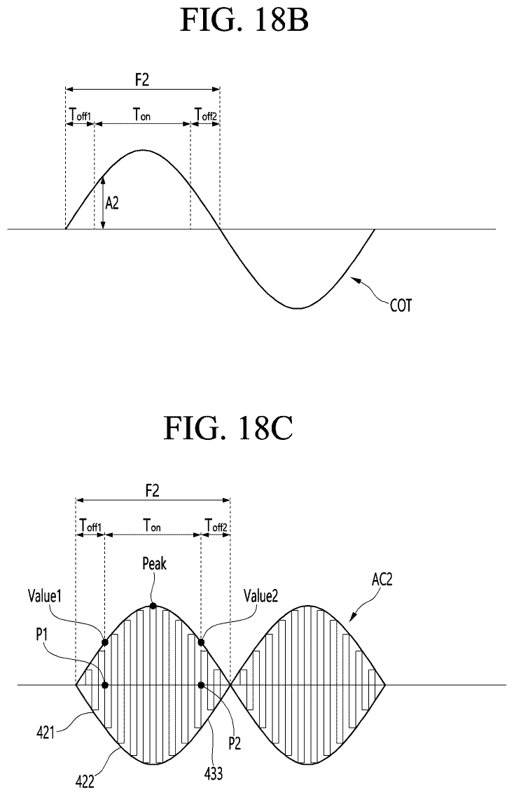

FIG. 18 illustrates a modulation of a first alternating current signal into a second alternating current signal according to a third embodiment.

Referring to FIG. 9, the signal supply device 440 can modulate the first alternating current signal AC1 (FIG. 18A) using the waveform of the control signal COT (FIG. 18B) to generate the second alternating current signal AC2 (FIG. 18C).

To this end, the control signal generation unit 442 can generate the control signal COT having a sine waveform.

The control signal COT can be configured as a waveform having a first OFF section Toff1, an ON section Ton, and a second OFF section Toff2 as one period F2. For example, during the first OFF section Toff1, a first control signal in which the amplitude A2 nonlinearly increases from 0 is generated, during the ON section1 Ton, a second control signal in which the amplitude A2 nonlinearly increases toward a peak value and then nonlinearly decreases is generated, and during the second OFF section Toff2, a third control signal in which the amplitude A2 nonlinearly decreases to 0 can be generated.

The modulation unit 443 can modulate the control signal COT into a symmetrical waveform (COT′ of FIG. 14) symmetrical to the time axis, and can generate a waveform corresponding to the modulated symmetrical waveform COT′ among the waveforms of the first alternating current signal AC1 as the waveform of the second alternating current signal AC2. Accordingly, each of the first to third control signals can be modulated into a symmetrical waveform COT′ symmetrical to the time axis for each of the first OFF section Toff1, the ON section1 Ton, and the second OFF section Toff2. Thereafter, the waveform of the first alternating current signal AC1 corresponding to the symmetrical waveform COT′ of each of the first to third control signals can be generated as the waveform of the second alternating current signal AC2.

Therefore, as illustrated in FIG. 18C, the second alternating current signal AC2 can have a second-first alternating current signal 431 corresponding to the first OFF section Toff1, a second-second alternating current signal 432 corresponding to the ON section Ton, and a second-third alternating current signal 433 corresponding to the second OFF section Toff2.

The second-first alternating current signal 431 can have an amplitude A2 that increases from 0 to a first value Value1, the second-second alternating current signal 432 can have an amplitude A2 that increases from the first value Value1 to a peak value (Peak), and then decreases from the peak value to a second value Value2, and the second-third alternating current signal 433 can have an amplitude A2 that decreases from the second value Value2 to 0. That is, the second alternating current signal AC2 may comprise the first alternating current signal AC1 corresponding to the symmetrical waveform (COT′ of FIG. 14) symmetrically modulated with the control signal COT on the time axis.

The second alternating current signal AC2 illustrated in FIG. 18C may be supplied to the first assembling wiring 321 and the second assembling wiring 322 of each of the first sub-pixel PX1, the second sub-pixel PX2, and the third sub-pixel PX3 of the display substrate 300 illustrated in FIG. 7, so that the dielectrophoretic force DEP formed between the first assembling wiring 321 and the second assembling wiring 322 may be periodically changed.

The dielectrophoretic force DEP may be formed during a specific section between the first point P1 corresponding to the first value Value1 and the second point P2 corresponding to the second value Value2, and the dielectrophoretic force DEP may not be formed before the first point P1 or after the second point P2.

For example, by the second-second alternating current signal 432 supplied during the ON period Ton of one period F2, the dielectrophoretic force DEP can be formed to the maximum between the first assembling wiring 321 and the second assembling wiring 322, so that the first semiconductor light-emitting element 150-1, the second semiconductor light-emitting element 150-2, and the third semiconductor light-emitting element 150-3 can be assembled into the assembly holes 330H of each of the first sub-pixel PX1, the second sub-pixel PX2, and the third sub-pixel PX3.

For example, the dielectrophoretic force DEP between the first assembling wiring 321 and the second assembling wiring 322 can be reduced by the second-first alternating current signal 431 supplied during the first OFF section Toff1 of one period F2 or the second-third alternating current signal 433 supplied during the second OFF section Toff2, so that the first semiconductor light-emitting element 150-1, the second semiconductor light-emitting element 150-2 and/or the third semiconductor light-emitting element 150-3, which are incorrectly-assembled in the assembly hole 330H of the first sub-pixel PX1, the second sub-pixel PX2 and/or the third sub-pixel PX3 during the ON section Ton, can be disassembled, i.e., detached.

Meanwhile, the second alternating current signal AC2 having the second-first alternating current signal 431, the second-second alternating current signal 432, and the second-third alternating current signal 433 may be supplied to the first assembling wiring 321 and the second assembling wiring 322 of each of the first sub-pixel PX1, the second sub-pixel PX2, and the third sub-pixel PX3. In this case, if the mis-assembled semiconductor light-emitting element is not detached during the second OFF section Toff2 of the first period during the ON section Ton of the first period, the mis-assembled semiconductor light-emitting element may be detached from the corresponding assembly hole 330H during the first OFF section Toff1 and the second OFF section Toff2 of each period, such as the second period, the third period, and the fourth period, and a semiconductor light-emitting element matching the corresponding assembly hole 330H may be correctly assembled in the corresponding assembly hole 330H during the ON section Ton of the next period.

According to the third embodiment, a second alternating current signal AC2 having a sine waveform may be generated by using a control signal COT having a sine waveform, and the second alternating current signal AC2 can be supplied to the first assembling wiring 321 and the second assembling wiring 322 of each of the first sub-pixel PX1, the second sub-pixel PX2, and the third sub-pixel PX3, so that the first semiconductor light-emitting element 150-1, the second semiconductor light-emitting element 150-2, and the third semiconductor light-emitting element 150-3 can be assembled to the display substrate 300 at the same time. In addition, even if the first semiconductor light-emitting element 150-1, the second semiconductor light-emitting element 150-2, and/or the third semiconductor light-emitting element 150-3 is incorrectly-assembled, the dielectrophoretic force DEP can be periodically changed to easily detach the first semiconductor light-emitting element from the corresponding assembly hole 330H. Therefore, the assembly rate can be maximized by minimizing the mis-assembly rate of the first semiconductor light-emitting element 150-1, the second semiconductor light-emitting element 150-2, and/or the third semiconductor light-emitting element 150-3, and the color mixing due to mis-assembly of the first semiconductor light-emitting element 150-1, the second semiconductor light-emitting element 150-2, and/or the third semiconductor light-emitting element 150-3 can be prevented, thereby improving product reliability.

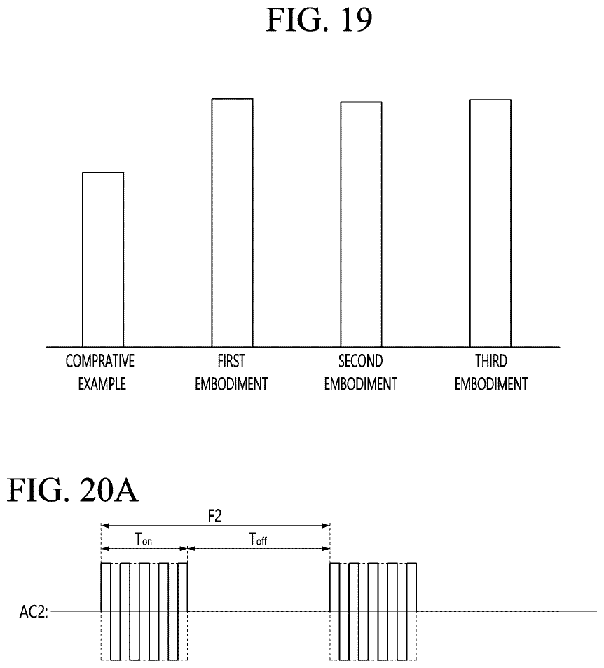

FIG. 19 shows the correct assembly rates in the comparative example and the first to third embodiments. The comparative example is when the first alternating current signal AC1 is supplied to the first assembling wiring 321 and the second assembling wiring 322 of the display substrate 300. The first embodiment is a case where a second alternating current signal AC2 of a square waveform is supplied to the first assembling wiring 321 and the second assembling wiring 322 of the display substrate 300, the second embodiment is a case where a second alternating current signal AC2 of a triangular waveform is supplied to the first assembling wiring 321 and the second assembling wiring 322 of the display substrate 300, and the third embodiment is a case where a second alternating current signal AC2 of a sine waveform is supplied to the first assembling wiring 321 and the second assembling wiring 322 of the display substrate 300.

As shown in FIG. 19, it can be seen that the correct assembly rate of all of the first to third embodiments is improved compared to the comparative example.

[symbol]

### Fourth Embodiment

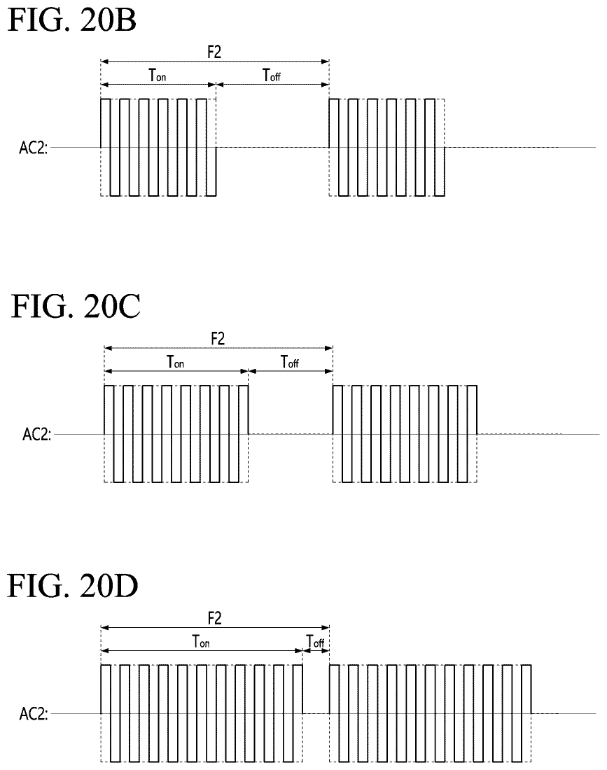

FIG. 20 illustrates a second alternating current signal according to a duty ratio according to the fourth embodiment.

The fourth embodiment can obtain an optimal range capable of accelerating the detachment of a mis-assembled semiconductor light-emitting element by adjusting the duty ratio of the second alternating current signal AC2 generated using the control signal COT having a square waveform in the first embodiment.

Although not shown, the optimal range capable of accelerating the detachment of a mis-assembled semiconductor light-emitting element can also be obtained by adjusting the duty ratio of the second alternating current signal AC2 generated using the control signal COT having a triangular waveform in the second embodiment or the control signal COT having a sine waveform in the third embodiment.

The duty ratio can be the ratio of the ON section Ton to the sum of the ON section Ton and the OFF section of the control signal COT.

By adjusting the width of the On section Ton of the control signal COT, the duty ratio of the second alternating current signal AC2 generated using the control signal COT can be adjusted to 30% (FIG. 20A), 50% FIG. 20B), 70% (FIG. 20C), and 90% (FIG. 20D).

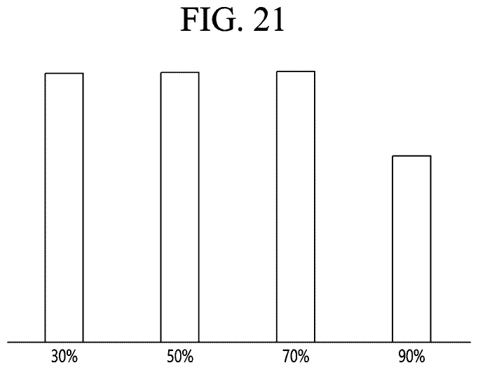

FIG. 21 shows the correct assembly rate according to the duty ratio.

As shown in FIG. 21, it can be seen that the correct assembly rate is higher when the duty ratio is 30% (FIG. 20A), 50% (FIG. 20B), and 70% (FIG. 20C) compared to when the duty ratio is 90% (FIG. 20D).

Therefore, when the duty ratio of the second alternating current signal AC2 is 30% to 70%, the dielectrophoretic force DEP formed between the first assembling wiring 321 and the second assembling wiring 322 of each of the first sub-pixel PX1, the second sub-pixel PX2, and the third sub-pixel PX3 of the display substrate 300 can be changed by the second alternating current signal AC2. In this case, the first semiconductor light-emitting element 150-1, the second semiconductor light-emitting element 150-2, and the third semiconductor light-emitting element 150-3 may be correctly assembled in the first sub-pixel PX1, the second sub-pixel PX2, and the third sub-pixel PX3, respectively, and even if the first semiconductor light-emitting element 150-1, the second semiconductor light-emitting element 150-2, and/or the third semiconductor light-emitting element 150-3 are incorrectly-assembled in the first sub-pixel PX1, the second sub-pixel PX2, and/or the third sub-pixel PX3, they can easily be detached from the corresponding assembly hole 330H.

When the duty ratio of the second alternating current signal AC2 is 90%, the OFF section of the second alternating current signal AC2 is too short, which means that the time for which the dielectrophoretic force DEP formed between the first assembling wiring 321 and the second assembling wiring 322 disappears is very short. Therefore, when the OFF section of the second alternating current signal AC2 is very short, the first semiconductor light-emitting element 150-1, the second semiconductor light-emitting element 150-2, and/or the third semiconductor light-emitting element 150-3 may not be easily detached from the corresponding assembly hole 330H and may still be fixed or attached to the corresponding assembly hole 330H, thereby lowering the correct assembly rate.

Meanwhile, the display device described above may be a display panel. That is, in the embodiment, the display device and the display panel may be understood to have the same meaning. In the embodiment, the display device in a practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment can be adopted in the display field for displaying images or information. The embodiment can be adopted in the display field for displaying images or information using a semiconductor light-emitting element. The semiconductor light-emitting element can be a micro-level semiconductor light-emitting element or a nano-level semiconductor light-emitting element.

For example, the embodiment can be adopted in TV, signage, smart phone, mobile phone, mobile terminal, HUDs for automobile, backlight unit for laptop, and display device for VR or AR.

1. A device for manufacturing a display device, comprises:
a chamber in which a display substrate is installed and comprising a fluid;
a magnetic member on one side of the display substrate; and
a signal supply device,
wherein the signal supply device is configured:
to modulate a first alternating current signal into a second alternating current signal and
to supply the modulated second alternating current signal to electrode wiring of the display substrate, and
wherein the second alternating current signal is configured to periodically change a dielectrophoretic force to attach and detach a plurality of semiconductor light-emitting elements contained in the fluid to a plurality of assembly holes of the display substrate, respectively.

2. The device of claim 1, wherein the signal supply device comprises:
an alternating current signal generation unit configured to generate the first alternating current signal;
a control signal generation unit configured to generate a control signal; and
a modulation unit configured to modulate the first alternating current signal into the second alternating current signal according to the control signal.

3. The device of claim 2, wherein the modulation unit is configured to modulate the control signal into a symmetrical waveform symmetrical to a time axis, and generate a waveform corresponding to the modulated symmetrical waveform among the waveforms of the first alternating current signal as the waveform of the second alternating current signal.

4. The device of claim 2, wherein the control signal is configured as a waveform having an ON section and an OFF section in one period.

5. The device of claim 4, wherein the second alternating current signal has a second-first alternating current signal corresponding to the ON section and a second-second alternating current signal corresponding to the OFF section, and
wherein the second-first alternating current signal has a rectangular waveform.

6. The device of claim 5, wherein the second-first alternating current signal comprises the first alternating current signal, and
wherein the second-second alternating current signal comprises a 0-level signal.

7. The device of claim 6, wherein the dielectrophoretic force is configured to be formed by the second-first alternating current signal, and
wherein the dielectrophoretic force is configured to be not formed by the second-second alternating current signal.

8. The device of claim 4, wherein a duty ratio is a ratio of the ON section to a sum of the ON section and the OFF section, and
wherein the duty ratio is 30% to 70%.

9. The device of claim 2, wherein the control signal is configured as a waveform having a first OFF section, an ON section, and a second OFF section as one period.

10. The device of claim 9, wherein the waveform comprises one of a triangular waveform or a sine waveform.

11. The device of claim 9, wherein the second alternating current signal has a second-first alternating current signal corresponding to the first OFF section, a second-second alternating current signal corresponding to the ON section, and a second-third alternating current signal corresponding to the second OFF section.

12. The device of claim 11, wherein the second-first alternating current signal has an amplitude that increases from 0 to a first value,
wherein the second-second alternating current signal has an amplitude that increases from the first value to a peak value and then decreases from the peak value to a second value, and
wherein the second-third alternating current signal has an amplitude that decreases from the second value to 0.

13. The device of claim 12, wherein the dielectrophoretic force is configured to be formed during a specific section between a first point corresponding to the first value and a second point corresponding to the second value, and
wherein the dielectrophoretic force is configured to be not formed before the first point or after the second point.

14. The device of claim 12, wherein the dielectrophoretic force is configured to increase and then decrease during a specific section.

15. The device of claim 1, wherein the plurality of semiconductor light-emitting elements comprise a plurality of first semiconductor light-emitting elements, a plurality of second semiconductor light-emitting elements, and a plurality of third semiconductor light-emitting elements.

16. The device of claim 15, wherein a shape of each of the first semiconductor light-emitting elements, the second semiconductor light-emitting elements, and the third semiconductor light-emitting elements is different,
wherein the plurality of assembly holes comprise a plurality of first assembly holes, a plurality of second assembly holes, and a plurality of third assembly holes, and
wherein the shapes of the first assembly holes, the second assembly holes, and the third assembly holes correspond to the shapes of the first semiconductor light-emitting elements, the second semiconductor light-emitting elements, and the third semiconductor light-emitting elements, respectively.

17. The device of claim 16, wherein the first semiconductor light-emitting element assembled in the first assembly hole is maintained in the assembly by changing the dielectrophoretic force, and the second semiconductor light-emitting element or the third semiconductor light-emitting element assembled in the first assembly hole is detached.

18. The device of claim 1, wherein the plurality of semiconductor light-emitting elements have a circular shape, an oval shape having a length of a first major axis, or an oval shape having a length of a second major axis greater than the length of the first major axis.
